(19) United States
(12) Patent Application Publication
(10) Pub. No.: US 2019/0165641 A1
(43) Pub. Date: May 30, 2019

(54) CIRCUIT BOARD, MOTOR, AND FAN MOTOR

(71) Applicant: Nidec Corporation, Kyoto (JP)

(72) Inventors: Yoshihiro ITO, Kyoto (JP); Osamu YANAGIMOTO, Kyoto (JP)

(21) Appl. No.: 16/181,428

(22) Filed: Nov. 6, 2018

(30) Foreign Application Priority Data
Nov. 30, 2017 (JP) 2017-230034

(51) Int. Cl. H02K 5/22; H02K 7/14; H02K 11/33; H02K 21/14; H05K 1/11; H05K 1/03; H05K 1/02; F04D 25/08

(52) U.S. Cl. CPC H02K 5/225; H02K 7/14; H02K 11/33; H02K 21/14; H05K 1/115; H05K 2201/09063; H05K 1/0269; F04D 25/08; H02K 2211/03; H05K 2201/09018; H05K 2201/09036; H05K 1/0366

(57) ABSTRACT

A motor that drives an impeller of a fan motor includes a rotor, stator, and circuit board. The circuit board is electrically connected to a controller that drives the rotor. When electrical connection between first and second signal lines is established, the rotor is drivable in a first mode. When electrical connection is cut, the rotor is drivable in a second mode. The circuit board includes a board, a protrusion protruding from an end of the board in a first direction perpendicular or substantially perpendicular to a board thickness direction, wiring portions, a first surface on one side in a second direction parallel or substantially parallel to the board thickness direction and a second surface on the other side. The wiring portions include first and second signal lines respectively provided on the first and second surfaces of the board and protrusion, the second signal line being electrically connected to the first signal line at the protrusion.

### CROSS REFERENCE TO RELATED APPLICATIONS

This application claims the benefit of priority to Japanese Patent Application No. 2017-230034 filed on Nov. 30, 2017. The entire contents of this application are hereby incorporated herein by reference.

### BACKGROUND OF THE INVENTION

### 1. Field of the Invention

The present invention relates to a circuit board, a motor, and a fan motor.

### 2. Description of the Related Art

To date, there has been a technique for selecting a function of a circuit mounted on a board by cutting a portion of the board. For example, in the electronic apparatus of Japanese Unexamined Patent Application Publication No. 2001-148549, at least one signal line is formed on one side of a printed board having a plurality of functions. This signal line is electrically disconnected by cutting a portion of the printed circuit board where the signal line is formed. The printed circuit board selects a function on the basis of whether the signal line is electrically connected or electrically disconnected. It is useful to apply such a technique to a circuit board for controlling a motor having a plurality of drive modes.

However, it is difficult to use a simple tool such as a nipper to cut off a portion of the board where the signal line is formed on one side thereof together with the electrical connection of the signal line. For example, a predetermined distance is provided between the signal line and an end surface of the board. In addition, for example, when two signal lines extend to and are electrically connected to a portion to be cut, it is necessary to provide a predetermined insulation distance between the respective signal lines. Therefore, the width required for cutting the board tends to be relatively wide. In addition, cracks are likely to occur in the board as a result of cutting.

### SUMMARY OF THE INVENTION

In view of the above circumstances, preferred embodiments of the present invention provide circuit boards that each enable electrical connection of a signal line to be more easily cut in a portion of the circuit board where the signal line is provided, and motor including such circuit boards, and fan motors.

A circuit board according to an exemplary embodiment of the present invention is a circuit board to be mounted on a motor, and includes a board that is plate-shaped, a protruding portion, wiring portions, a first surface, and a second surface. The protruding portion protrudes from an end portion of the board in a first direction perpendicular or substantially perpendicular to a thickness direction of the board. The wiring portions are provided on the board. The first surface is on one side in a second direction parallel or substantially parallel to the thickness direction of the board. The second surface is on another side in the second direction. The wiring portions include a first signal line and a second signal line. The first signal line is provided on the first surface of both the board and the protruding portion. The second signal line is provided on the second surface of both the board and the protruding portion, and is electrically connected to the first signal line at the protruding portion.

A motor according to an exemplary embodiment of the present invention includes a rotor, a stator, and the circuit board. The rotor is rotatable about a central axis. The stator drives the rotor. The circuit board is electrically connected to a drive control unit that drives the rotor in a plurality of drive modes. When electrical connection between the first signal line and the second signal line is established, the rotor is drivable in a first drive mode. When electrical connection between the first signal line and the second signal line is cut, the rotor is drivable in a second drive mode.

A fan motor according to an exemplary embodiment of the present invention includes an impeller including a plurality of blades rotatable about the central axis and the motor, which drives the impeller.

According to the exemplary embodiments of circuit boards, motors, and fan motors of the present invention, the electrical connection of the signal line is able to be more easily cut at the portion where the signal line of the circuit board is provided.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a fan motor.

FIG. 2 is a sectional view of the fan motor.

FIG. 3 is a top view of a circuit board.

FIG. 4 is a sectional view of the inside of the circuit board viewed from an axial direction.

FIG. 5 is an enlarged top view of a protruding portion.

FIG. 6 is a sectional view of the protruding portion.

FIG. 7 is a top view illustrating another wiring example of a first signal line and a second signal line.

### DETAILED DESCRIPTION OF THE PREFERRED EMBODIMENTS

Exemplary embodiments of the present invention will be described below with reference to the drawings. Further, in this specification, with regard to a fan motor 100 described later, the rotational axis of a rotor 1 and an impeller 120 of a motor 110 (to be described later) will be referred to as “central axis CA”. In addition, the direction parallel or substantially parallel to the central axis CA will be referred to as “axial direction”. Furthermore, the direction from a circuit board 7 (to be described later) toward the impeller 120 (to be described later) along the axial direction will be referred to as “axial-direction upper side”, and the direction from the impeller 120 to the circuit board 7 along the axial direction will be referred to as “axial-direction lower side”. Among the surfaces of each constituent element, a surface facing toward the axial-direction upper side will be referred to as “upper surface” and a surface facing toward the axial-direction lower side will be referred to as “lower surface”. In addition, in each constituent element, an end portion on the axial-direction upper side will be referred to as “upper end portion” and an end portion on the axial-direction lower side will be referred to as “lower end portion”.

A direction in which a straight line perpendicular or substantially perpendicular to the central axis CA extends will be referred to as “radial direction”. Furthermore, a direction toward the central axis CA along the radial direction will be referred to as “radial-direction inner side” and a direction away from the central axis CA along the radial direction will be referred to as “radial-direction outer side”. Among the surfaces of each constituent element, a side surface facing toward the radial-direction inner side will be referred to as “inner side surface” and a side surface facing toward the radial-direction outer side will be referred to as “outer side surface”. In addition, in each constituent element, an end portion on the radial-direction inner side will be referred to as “inner end portion” and an end portion on the radial-direction outer side will be referred to as “outer end portion”.

The direction of rotation about the central axis CA will be referred to as “circumferential direction”.

With respect to a protruding portion 72 (described later) of the circuit board 7, the direction in which the protruding portion 72 protrudes from a board 71 (to be described later) will be referred to as “first direction Ax1”. The direction parallel or substantially parallel to the thickness direction of the board 71, which is plate-like, will be referred to as “second direction Ax2”. The direction perpendicular or substantially perpendicular to the first direction Ax1 and the second direction Ax2 will be referred to as “third direction Ax3”. Further, in the present embodiment, the first direction Ax1 is perpendicular or substantially perpendicular to the thickness direction of the board 71. The second direction Ax2 is parallel or substantially parallel to the axial direction. In addition, one side of the second direction Ax2 corresponds to the axial-direction upper side and the other side of the second direction Ax2 corresponds to the axial-direction lower side. The first direction Ax1, the second direction Ax2, and the third direction Ax3 are perpendicular or substantially perpendicular to each other.

Further, note that the above-mentioned designations such as those of the directions, surfaces, and end portions do not indicate positional relationship, direction, and the like in the case of being incorporated in an actual device.

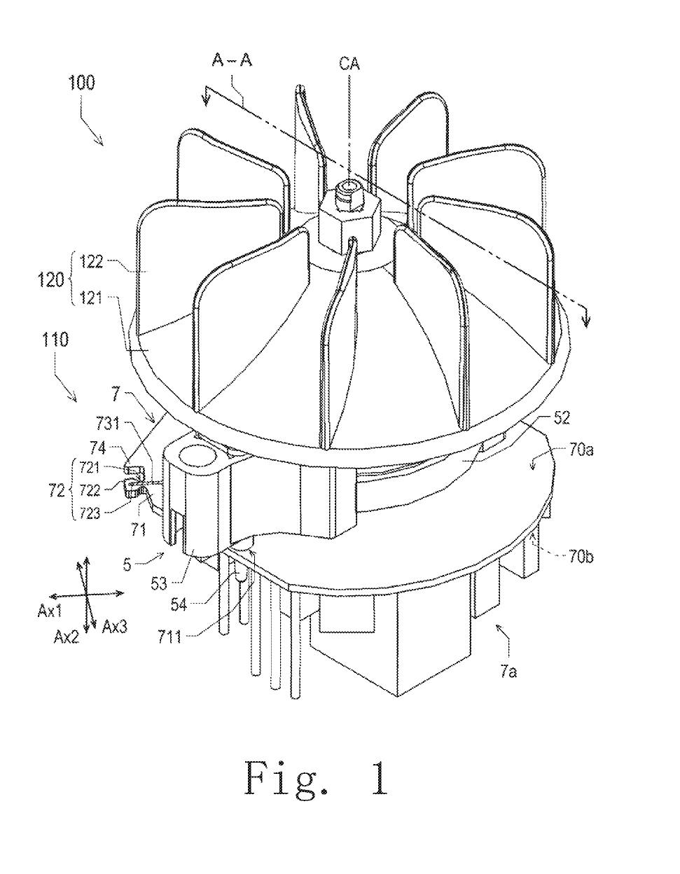

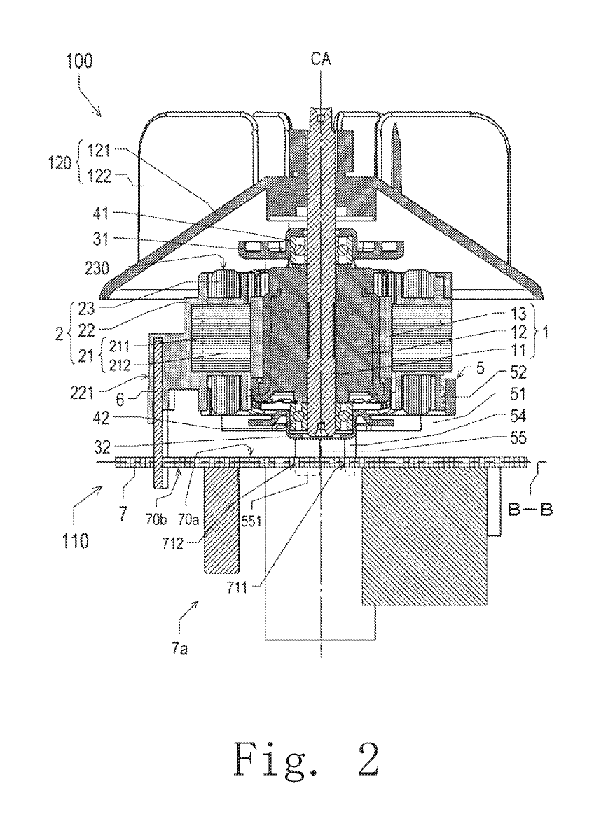

FIG. 1 is a perspective view of the fan motor 100. FIG. 2 is a sectional view of the fan motor 100. Further, FIG. 2 illustrates a sectional structure in a case where the fan motor 100 is virtually cut along a two-dot chain line A-A in FIG. 1 in a plane including the central axis CA and parallel or substantially parallel to the axial direction.

As illustrated in FIG. 1, in the present embodiment, the fan motor 100 includes the motor 110 and the impeller 120. The motor 110 drives the impeller 120 so as to rotate. The impeller 120 is an impeller attached to an upper portion of the motor 110 and has an impeller base 121 and a plurality of blades 122. The impeller base 121 is attached to the rotor 1 (to be described later) of the motor 110, and more specifically attached to a shaft (to be described later). The plurality of blades 122 are provided on the upper surface of the impeller base 121 and are rotatable around the central axis CA that extends in the vertical direction. The blades 122 project upward in the axial direction and, among the radial direction and the circumferential direction, extend at least in the radial direction. The impeller 120 is driven by the motor 110 so as to rotate around the shaft 11 and generates an airflow.

The motor 110 is a driving device that drives and rotates the impeller 120, and is, for example, to be mounted in an electric device such as a dryer. Further, although the motor 110 is an inner rotor type motor in the present embodiment, it is not limited to this example, and may be an outer rotor type motor.

As illustrated in FIG. 2, the motor 110 includes the rotor 1, a stator 2, an upper bearing holder 31, a lower bearing holder 32, an upper bearing 41, a lower bearing 42, a bracket 5, a terminal portion 6, and the circuit board 7 mounted on an electronic component 7a.

The rotor 1 is rotatable about the central axis CA. The rotor 1 has the shaft 11, a holding member 12, and a magnet 13.

The shaft 11 extends in the axial direction with the central axis CA as the center thereof. In the present embodiment, the impeller 120, the holding member 12 that holds the magnet 13, a portion of the upper bearing 41, and a portion of the lower bearing 42 are attached to the outer surface of the shaft 11. The shaft 11, together with these elements, is rotatable about the central axis CA.

The holding member 12 has a cylindrical shape extending in the axial direction with the central axis CA as the center thereof. The shaft 11 is in communication with the center of the holding member 12. In addition, the magnet 13 is provided on the outer surface of the holding member 12.

The magnet 13 has a plurality of magnetic poles and faces the stator 2 in the radial direction. With regard to the plurality of magnetic poles, for example, magnetic poles different from each other are alternately arranged in the circumferential direction.

The stator 2 faces the rotor 1 in the radial direction and drives the rotor 1. In the present embodiment, the stator 2 is located on the radial-direction outer side of the rotor 1 and is fixed to the bracket 5. The stator 2 has a stator core 21, an insulator 22, and a plurality of coil portions 23.

The stator core 21 has an annular shape with the central axis CA as the center thereof, and, for example, is formed of a laminated steel plate in which electromagnetic steel plates are laminated in the axial direction. In the present embodiment, the stator core 21 is located on the radial-direction outer side of the magnet 13. In addition, the inner side surface of the stator core 21 faces the outer side surface of the magnet 13 in the radial direction. The stator core 21 has a core back 211, which is annular, with the central axis CA as the center thereof and a plurality of teeth 212 extending from the core back 211 toward the radial-direction inner side.

The insulator 22 is, for example, an insulating member formed of a resin material and covers at least a portion of the stator core 21. The insulator 22 electrically insulates the stator core 21 and the coil portions 23 from each other. In addition, as illustrated in FIG. 2, the insulator 22 has an insulator protruding portion 221. The insulator protruding portion 221 protrudes toward the radial-direction outer side in a partial region in the circumferential direction of the outer side surface of the insulator 22. An upper end portion of the terminal portion 6 electrically connected to the circuit board 7 is fixed to the insulator protruding portion 221.

Each of the coil portions 23 is composed of a conductive wire 230 wound around the teeth 212 of the stator core 21 via the insulator 22. The conductive wire 230 is a metal wire covered with an insulating member such as an enamel coated copper wire or the like. When a drive current is supplied to the coil portions 23, a magnetic flux in the radial direction is generated in the stator core 21. Using the magnetic flux, the stator 2 generates circumferential torque on the rotor 1 and rotates the rotor 1 around the central axis CA. The end portion of the conductive wire 230 is tied and electrically connected to the terminal portion in a state where the insulating layer has been peeled off. Therefore, each of the coil portions 23 is electrically connected to the circuit board 7 via the terminal portion 6.

The upper bearing holder 31 is, for example, a metal bearing holding portion formed of a metal, is held by the stator 2, and supports the shaft 11 via the upper bearing 41 so as to be rotatable. In the present embodiment, the upper bearing holder 31 is provided on the axial-direction upper side of the holding member 12 of the rotor 1 and holds the outer end portion of the upper bearing 41.

The lower bearing holder 32 is, for example, a metal bearing holding portion formed of a metal, held by the bracket 5, and supporting the shaft 11 via the lower bearing 42 so that the shaft 11 is rotatable. In the present embodiment, the lower bearing holder 32 is provided on the axial-direction lower side of the holding member 12 of the rotor 1 and holds the outer end portion of the lower bearing 42.

In the present embodiment, the upper bearing 41 and the lower bearing 42 are ball bearings, but the present invention is not limited to this example, and sleeve bearings or the like may be used.

The bracket 5 holds the stator 2, and in this embodiment holds the stator core 21 and the lower bearing holder 32. The bracket 5 has a plate portion 51, a side wall portion 52, a fixing portion 53, a column portion 54, and an attachment portion 55.

The plate portion 51 has a plate shape that intersects with the central axis CA. In the present embodiment, the plate portion 51 extends in the radial direction. The lower bearing holder 32 is fixed to the plate portion 51.

The side wall portion 52 protrudes toward the axial-direction upper side from the outer end portion of the plate portion 51, extends in the circumferential direction, and houses at least a portion of the stator 2 therein. In the present embodiment, the side wall portion 52 houses the lower end portion of the stator 2, more specifically, houses a portion of the insulator 22 and a portion of the coil portions 23 on the axial-direction lower side of the stator core 21.

The fixing portion 53 is provided at the outer end portion of the plate portion 51 and is aligned with the side wall portion 52 in the circumferential direction. The fixing portion 53 extends toward the axial-direction upper side from the outer end portion of the plate portion 51 and contacts a portion of the outer side surface of the stator core 21 so as to hold the stator core 21. In addition, the fixing portion 53 projects toward the radial-direction outer side at the outer end portion of the plate portion 51. The number of the fixing portions 53 may be one, but is preferably plural, and is two in this embodiment. Further, when there are a plurality of the fixing portions 53, it is preferable that they are equally distributed in the circumferential direction, that is, arranged at regular intervals.

The column portion 54 and the attachment portion 55 extend toward the axial-direction lower side from the lower surface of the fixing portion 53 and are attached to the circuit board 7. For example, the column portion 54 is fitted into a through hole 711 of the circuit board 7. In addition, the attachment portion 55 has, for example, a claw portion 551. The attachment portion 55 is inserted through a board recessed portion 712 of the circuit board 7, and the claw portion 551 is hooked on the lower surface of the circuit board 7. As a result, the circuit board 7 is attached to the bracket 5 by so-called snap fitting.

The circuit board 7 is located on the axial-direction lower side of the rotor 1 and the stator 2 and is electrically connected to the stator 2 and a drive control unit (not illustrated). The drive control unit can drive the rotor 1 in a plurality of drive modes, and is provided outside the fan motor 100 in the present embodiment. However, the present invention is not limited to this example, and the drive control unit may be provided inside the fan motor 100, for example, it may be a portion of the electronic component 7a mounted on the circuit board 7.

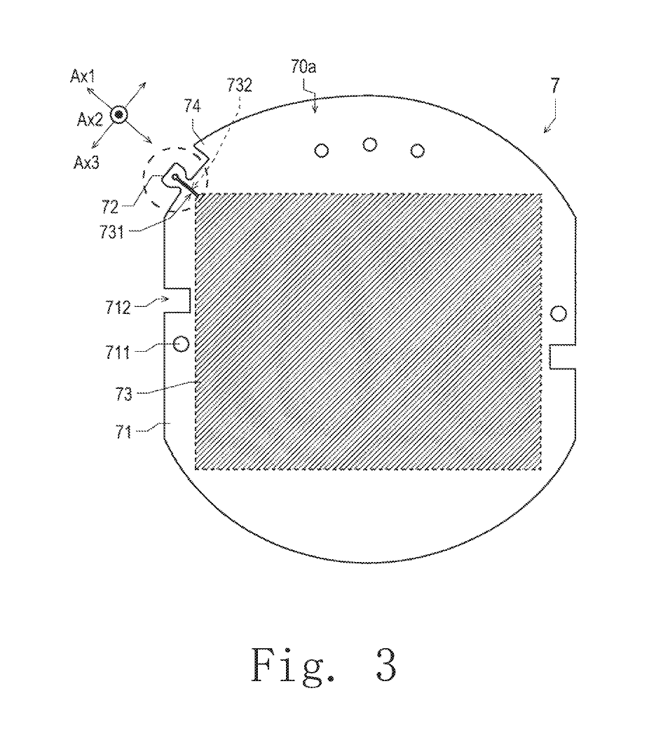

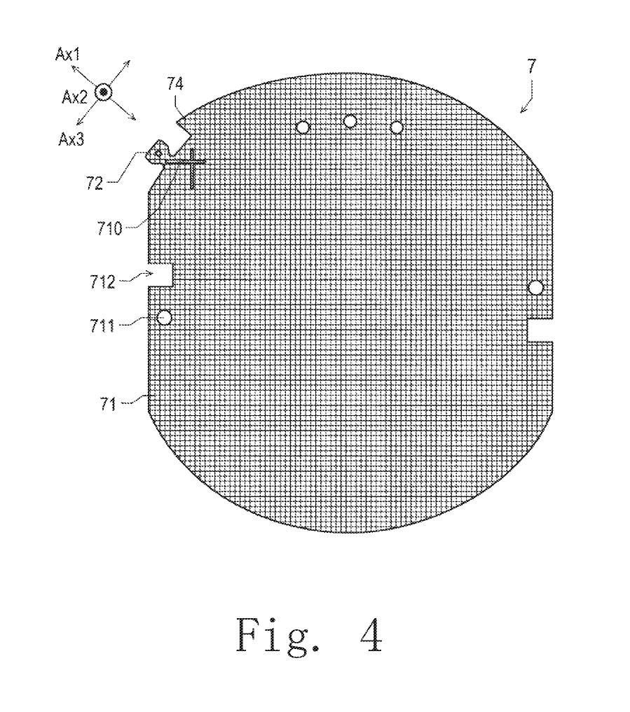

A specific configuration of the circuit board 7 to be mounted on the motor 110 will be described. FIG. 3 is a top view of the circuit board 7. FIG. 4 is a sectional view of the inside of the circuit board 7 as seen from the axial direction. FIG. 4 illustrates a sectional structure in a case where the circuit board 7 is virtually cut along a plane perpendicular or substantially perpendicular to the axial direction along a two-dot chain line B-B in FIG. 2.

The circuit board 7 has the board 71, which is plate-shaped, the protruding portion 72, wiring portions 73, and a piece 74. In the present embodiment, the board 71, the protruding portion 72, and the piece 74 are each a portion of the same member. In addition, as illustrated in FIG. 1 and FIG. 2, the circuit board 7 has an upper surface 70a on one side in the second direction Ax2 parallel or substantially parallel to the thickness direction of the board 71 and a lower surface 70b on the other side in the second direction Ax2. Further, the upper surface 70a of the circuit board 7 includes the upper surface of the board 71 and the upper surface of the protruding portion 72, and the lower surface 70b of the circuit board 7 includes the lower surface of the board 71 and the lower surface of the protruding portion 72. Therefore, in the following description, the upper surfaces of the circuit board 7, the board 71, and the protruding portion 72 are collectively referred to as the “upper surface 70a”, and the lower surfaces of the circuit board 7, the board 71, and the protruding portion 72 are collectively referred to as the “lower surface 70b”. In addition, the upper surface 70a is an example of the “first surface” in the present invention, and the lower surface 70b is an example of the “second surface” in the present invention.

As illustrated in FIG. 4, the board 71 is formed of a composite resin material that includes fibers 710 such as glass fibers, and in this embodiment, is formed using a composite resin material in which the fibers 710 are mixed in an epoxy resin. Further, in this embodiment, like the board 71, the protruding portion 72 and the piece 74 are also formed of a composite resin material containing the fibers 710 such as glass fibers.

In the present embodiment, the board 71 is larger than the rotor 1, the stator 2, and the side wall portion 52 of the bracket 5 when viewed from the axial direction, but is not limited to this example, and may be smaller than at least some of these. More specifically, when viewed from the axial direction, the outer end portion of the board 71 is located on the radial-direction outer side of the rotor 1, the stator 2, and the side wall portion 52 of the bracket 5 in the present embodiment, but is not limited to this example and may be located on the radial-direction inner side of at least some of these.

The board 71 has the through hole 711, the board recessed portion 712, and a mark portion 713. The through hole 711 and the board recessed portion 712 penetrate the board 71 in the axial direction. The board recessed portion 712 is recessed in a direction from the outside to the inside of the board 71 at an end portion of the board 71 when viewed from the second direction Ax2. As described above, the column portion 54 of the bracket 5 is fitted into the through hole 711. In addition, the attachment portion 55 of the bracket 5 is inserted through the board recessed portion 712. Then, the claw portion 551 of the attachment portion 55 is hooked on an end portion of the lower surface 70b of the board 71. With these configurations, when attaching the circuit board 7 to the bracket 5, it is possible to easily position the circuit board 7 in the circumferential direction and the radial direction. The configuration of the mark portion 713 will be described later.

The protruding portion 72 protrudes from the end portion of the board 71 in the first direction Ax1 perpendicular or substantially perpendicular to the thickness direction of the board 71. Further, as illustrated in FIG. 4, the first direction Ax1, which is the direction in which the protruding portion 72 protrudes, diagonally intersects the longitudinal direction of the fibers 710. The minimum angle between the first direction Ax1 and the longitudinal direction of the fibers 710 is preferably 30 degrees to 60 degrees. By doing so, it is possible to suppress the formation of cracks and the like in the board 71. For example, in a printed circuit board formed of an epoxy resin material containing glass fibers, the longitudinal direction of the glass fibers extends in two perpendicular directions. Therefore, in the case where the protruding portion 72 extends parallel or substantially parallel to one of the two perpendicular directions, when the protruding portions 72 is cut, cracks are generated in parallel with one of the two perpendicular directions making it difficult to stop crack growth with the glass fibers. On the other hand, according to the configuration of the present embodiment, because the protruding portion 72 extends diagonal to the two perpendicular directions, the above-described crack growth can be easily stopped by the fibers 710. Further, the specific structure of the protruding portion 72 will be described later.

The wiring portions 73 are provided on the board 71, and is electrically connected to the stator 2, the electronic component 7a, and a device, an electric circuit, and the like outside the fan motor 100. The wiring portions 73 include a first signal line 731 and a second signal line 732. The first signal line 731 is provided on the upper surface 70a of both the board 71 and the protruding portion 72. The second signal line 732 is provided on the lower surface 70b of both the board 71 and the protruding portion 72. The first signal line 731 and the second signal line 732 extend from the wiring portions 73 toward the tip of the protruding portion 72. In addition, the second signal line 732 is electrically connected to the first signal line 731 at the protruding portion 72.

In this way, the first signal line 731 and the second signal line 732 are provided on both the upper surface 70a and the lower surface 70b of the protruding portion 72 of the circuit board 7 in the second direction Ax2 and extend toward the tip of the protruding portion 72. Therefore, if the protruding portion 72 is cut, the electrical connection between the first signal line 731 and the second signal line 732 on the board 71 can also be cut. Accordingly, it is possible to easily cut the portion of the circuit board 7 where the first signal line 731 and the second signal line 732 are provided and, at the same time, cut the electrical connection between the first signal line 731 and the second signal line 732.

As compared with the case where the first signal line 731 and the second signal line 732 are provided on the same surface, for example, the upper surface 70a, it is possible to increase the creepage distance between the first signal line 731 on the upper surface 70a and the second signal line 732 on the lower surface 70b. Therefore, it is possible to decrease the width of the cuttable portion of the protruding portion 72. Therefore, it is easy to cut the protruding portion 72, and the formation of cracks or the like in the board 71 at the time of cutting can be reduced or prevented.

If the protruding portion 72 is not cut, the electrical connection between the first signal line 731 and the second signal line 732 is established. In this case, the rotor 1 can be driven in the first drive mode. On the other hand, when the protruding portion 72 is cut, the electrical connection between the first signal line 731 and the second signal line 732 is cut. In this case, the rotor 1 can be driven in the second drive mode different in rotational speed and the like from the first drive mode. In this way, it is possible to more easily cut the protruding portion 72 together with the first signal line 731 and the second signal line 732. In addition, by cutting the electrical connection between the first signal line 731 and the second signal line 732, the drive mode of the motor 110 can be changed.

When viewed from the axial direction, the tip of the first signal line 731 and the tip of the second signal line 732 are located outside the motor 110 as illustrated in FIG. 1. For example, when viewed from the axial direction, an end portion of one side of the first signal line 731 in the first direction Ax1 and an end portion of one side of the second signal line 732 in the first direction Ax1 are located on the radial-direction outer side of the stator 2, and furthermore, on the radial-direction outer side of the rotor 1 and the side wall portion 52 of the bracket 5 in the present embodiment. Therefore, for example, it is possible to grip a portion of the protruding portion 72 located outside the motor 110 by using a tool such as pliers and, in this state, break off the protruding portion 72. In this way, in a state where the circuit board 7 is attached to the stator 2, the electrical connection between the first signal line 731 and the second signal line 732 can be cut more easily.

Further, In the protruding portion 72, the portion where the first signal line 731 and the second signal line 732 are electrically connected to each other need not be located outside the motor 110, but is preferably located outside the motor 110. In the present embodiment, a through hole 723 (to be described later) is located on the radial-direction outer side of the stator 2 and the side wall portion 52 of the bracket 5 as illustrated in FIG. 1. The first signal line 731 and the second signal line 732 are electrically connected via the through hole 723. By doing so, the electrical connection between the first signal line 731 and the second signal line 732 can be cut by cutting off the portion of the protruding portion 72 that is located outside the motor 110.

The protruding portion 72 is usually cut at a portion that is narrowest in a direction intersecting the first direction Ax1 and perpendicular or substantially perpendicular to the second direction Ax2. This portion need not be located outside the motor 110, but is preferably located outside the motor 110. That is, in the first direction Ax1, a portion of the protruding portion 72 that is narrowest in a direction intersecting the first direction Ax1 and perpendicular or substantially perpendicular to the second direction Ax2 is preferably located on the radial-direction outer side of the stator 2. For example, in the present embodiment, the width is the narrowest at a connecting portion 722 of the protruding portion 72, and the connecting portion 722 is located on the radial-direction outer side of the stator 2. Furthermore, the connecting portion 722 is located on the radial-direction outer side of the rotor 1 and the side wall portion 52 of the bracket 5. In this way, in a state where the motor 110 has been assembled, it is possible to easily cut the protruding portion 72 and, at the same time, cut the first signal line 731 and the second signal line 732.

Next, at an end portion of the board 71 in a direction perpendicular or substantially perpendicular to the second direction Ax2 and in the vicinity of the protruding portion 72, the piece 74 protrudes from the inside of the board 71 to the outside. In the present embodiment, the piece 74 is positioned on one side in the third direction Ax3 with respect to the protruding portion 72 and faces one side of the protruding portion 72 in the third direction Ax3. Further, note that the present invention is not limited to this example and that two pieces 74 may be located on both sides of the protruding portion 72 in the third direction Ax3 and each of the pieces may face the protruding portion 72 in the third direction Ax3. That is, the piece 74 is located on at least one side of the protruding portion 72 in the third direction Ax3 and may face at least one side of the protruding portion 72 in the third direction Ax3. In this way, it is easy to prevent collisions between the protruding portion 72 and objects outside the circuit board 7 by provision of the piece 74. Therefore, the occurrence of cutting of the electrical connection between the first signal line 731 and the second signal line 732 due to accidental breakage of the protruding portion 72 can be reduced or prevented.

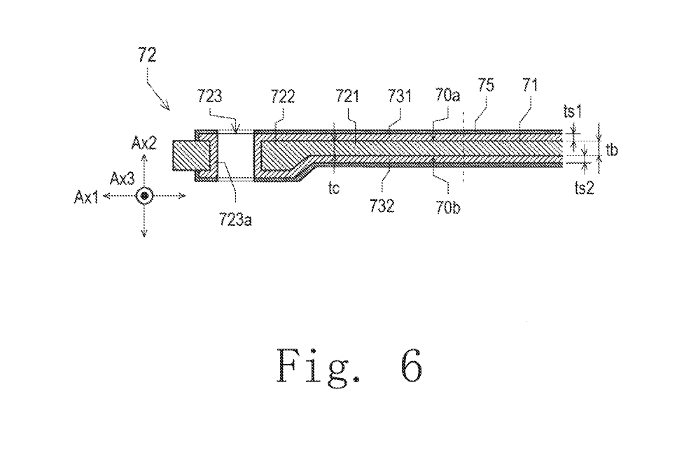

In addition, the circuit board 7 further has a resist film 75 as illustrated in FIG. 6 (to be described later). The resist film 75 is a film having electrical insulating properties and covers at least surfaces of the wiring portions 73, the first signal line 731, and the second signal line 732.

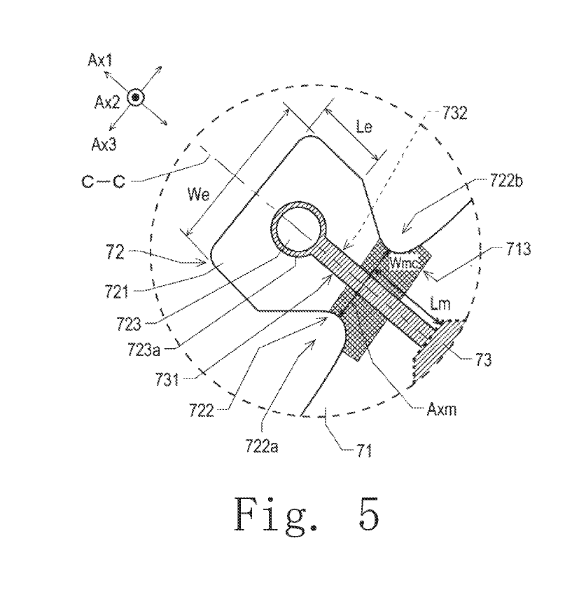

Next, a specific configuration of the protruding portion 72 will be described. FIG. 5 is an enlarged top view of the protruding portion 72. FIG. 6 is a sectional view of the protruding portion 72. Further, note that FIG. 5 corresponds to the portion surrounded by the circular broken line in FIG. 3. In addition, FIG. 6 illustrates a sectional structure in the vicinity of the protruding portion 72 in the case where the board 71 and the protruding portion 72 are virtually cut along the two-dot chain line C-C in FIG. 5.

As illustrated in FIG. 5 and FIG. 6, the protruding portion 72 has a tip portion 721, the connecting portion 722, and the through hole 723. The tip portion 721 is provided at the tip of the connecting portion 722. The connecting portion 722 extends in the first direction Ax1 from an end portion of the board 71. An end portion of the connecting portion 722 on one side in the first direction Ax1 is connected to the tip portion 721. An end portion of the connecting portion 722 on the other side in the first direction Ax1 is connected to the board 71. The through hole 723 is provided in the tip portion 721 and passes through the tip portion 721 in the second direction Ax2, which is the thickness direction of the tip portion 721. The through hole 723 has a conductive layer 723a having electrical conductivity. The conductive layer 723a is provided in regions of the upper surface 70a and the lower surface 70b of the tip portion 721 along the peripheral edge portions of the through hole 723 and also on the inner surface of the through hole 723. Alternatively, the through hole 723 may be filled with the conductive layer 723a.

The first signal line 731 is provided on the upper surface 70a of both the tip portion 721 and the connecting portion 722. The second signal line 732 is provided on the lower surface 70b of both the tip portion 721 and the connecting portion 722. The first signal line 731 and the second signal line 732 are electrically connected to the conductive layer 723a. That is, in the tip portion 721, the first signal line 731 is electrically connected to the second signal line 732 via the conductive layer 723a. Further, although the first signal line 731 and the second signal line 732 extend in a direction parallel or substantially parallel to the first direction Ax1 in the present embodiment, the present invention is not limited to this example, and the first signal line 731 and the second signal line 732 may be disposed in a direction diagonally intersecting the first direction Ax1 and the third direction Ax3 and perpendicular or substantially perpendicular to the second direction Ax2.

The width of the connecting portion 722 in a direction intersecting the first direction Ax1 and perpendicular or substantially perpendicular to the second direction Ax2 is minimum in a minimum width direction Axm as illustrated in FIG. 5. In the present embodiment, because the minimum width direction Axm is parallel or substantially parallel to the third direction Ax3, the connecting portion 722 has a minimum width Wmc in the third direction Ax3. As illustrated in FIG. 5, the minimum width Wmc of the connecting portion 722 in the minimum width direction Axm is smaller than the width We of the tip portion 721 in the third direction Ax3 perpendicular or substantially perpendicular to the first direction Ax1 and the second direction Ax2. That is, Wmc<We. In this way, by cutting the connecting portion 722, it is possible to easily cut the portion of the circuit board 7 where the first signal line 731 and the second signal line 732 are provided and, at the same time, cut the electrical connection between the first signal line 731 and the second signal line 732.

As illustrated in FIG. 5 and FIG. 6, the length Le of the tip portion 721 in the first direction Ax1 and the width We of the tip portion 721 in the third direction Ax3 are larger than the thickness tc of the connecting portion 722 in the second direction Ax2. However, the present invention is not limited to this example, and one of the length Le and the width We of the tip portion 721 may be larger than the thickness tc of the connecting portion 722 and the other may be smaller than the thickness tc. That is, Le>tc and/or We>tc may be satisfied. Here, the thickness tc is the thickness of the connecting portion 722 excluding the thickness ts1 of the first signal line 731 and the thickness ts2 of the second signal line 732. That is, in FIG. 6, the thickness tc illustrates the thickness in the case where the resist film 75 is not directly provided on the upper surface and the lower surface of the connecting portion 722. However, in the case where, for example, the resist film 75 or the like is directly provided on the upper surface and/or the lower surface of the connecting portion 722, the thickness tc of the connecting portion 722 is not limited to that in the illustration in FIG. 6 and may include the thickness of the resist film 75 or the like.

In this way, the area of the tip portion 721 as viewed from the second direction Ax2 becomes relatively large. Therefore, for example, because the tip portion 721 can be easily pinched by a tool such as a pliers, in this state, it is easy to perform a process of bending the connecting portion 722 and removing the tip portion 721. In addition, it is possible to secure sufficient space at the tip portion for the through hole 723, which is used for electrically connecting the first signal line 731 and the second signal line 732 to each other, and the like.

Further, the thickness tc of the connecting portion 722 in the second direction Ax2 is equal to the thickness tb of the board 71 in the second direction Ax2 in this embodiment. However, the thickness tc of the connecting portion 722 is not limited to this example and may be different from the thickness tb. In addition, also, tc>tb may be satisfied, but preferably tc<tb. By doing so, it is easier to perform a process of bending the connecting portion 722 to remove the tip portion 721. Here, the thickness tb illustrates the thickness in the case where the resist film 75 is not directly provided on the upper surface and the lower surface of the board 71 in FIG. 6. However, in the case where the resist film 75 or the like is directly provided on the upper surface and/or the lower surface of the board 71, the thickness tb of the board 71 is not limited to that in the illustration in FIG. 6, and may include the thickness of the resist film 75 and the like.

In addition, in the present embodiment, the protruding portion 72 further has a first recessed portion 722a and a second recessed portion 722b. The first recessed portion 722a is recessed toward the other side in the third direction Ax3 on one side of the protruding portion 72 in the third direction Ax3. The second recessed portion 722b is recessed to one side in the third direction Ax3 on the other side of the protruding portion 72 in the third direction Ax3. In this way, the connecting portion 722 can be formed between the first recessed portion 722a and the second recessed portion 722b. Therefore, the connecting portion 722 can be easily cut, and the connecting portion 722 can be easily cut particularly in the minimum width direction Axm in which the first recessed portion 722a and the second recessed portion 722b are the closest to each other.

Further, note that the present invention is not limited to the example of the present embodiment and the protruding portion 72 may have only one of the first recessed portion 722a and the second recessed portion 722b. In other words, the protruding portion 72 may have a recessed portion at one end portion in a direction intersecting with the first direction Ax1 and perpendicular or substantially perpendicular to the second direction Ax2 and have no recessed portion at the other end portion. Even in this case, compared with the configuration in which the protruding portion 72 does not have recessed portions at the end portions on both sides in the above-described direction, the protruding portion 72 can be easily cut.

Next, in the connecting portion 722, the mark portion 713 is provided on at least one of the upper surface 70a and the lower surface 70b. In this way, the mark portion 713 can clearly indicate the cutting site of the protruding portion 72.

The mark portion 713 is further provided on the connecting portion 722 or across the connecting portion 722 and the board 71 on at least one of the upper surface 70a and the lower surface 70b of the board 71. By doing so, cracks and the like heading from the cut portion of the protruding portion 72 toward the board 71 can be easily found. For example, if the mark portion 713 is a mark printed on a surface by silk printing or the like, it is easy to find cracks or the like by checking the presence or absence of cracks in the mark or the like.

In the connecting portion 722, the direction in which the first signal line 731 extends and the direction in which the second signal line 732 extends are perpendicular or substantially perpendicular to the minimum width direction Axm. This makes it easier to cut the first signal line 731 and the second signal line 732 with the cutting of the connecting portion 722.

In the second direction Ax2, the thickness ts1 of the first signal line 731 and the thickness ts2 of the second signal line 732 are each smaller than the thickness tc of the connecting portion 722. Further, the thickness tc is the thickness of the connecting portion 722 excluding the thickness ts1 of the first signal line 731 and the thickness ts2 of the second signal line 732. In this way, the thicknesses ts1 and ts2 of the first signal line 731 and the second signal line 732 are smaller than the thickness tc of the connecting portion 722. Therefore, when cutting the protruding portion 72, the electrical connection between the first signal line 731 and the second signal line 732 can be easily cut.

The wiring portions 73 other than the first signal line 731 and the second signal line 732 are disposed at positions separated from the position where the width of the connecting portion 722 is the minimum in the minimum width direction Axm by a distance larger than the thickness tb of the board 71. In this way, the wiring portions 73 other than the first signal line 731 and the second signal line 732 are sufficiently separated from the position where the width of the connecting portion 722 becomes minimum in the minimum width direction Axm. Therefore, even if a crack or the like going from the cut portion to the board 71 occurs, it is possible to suppress or prevent adverse influence on the wiring portions 73 on the board 71.

Further, in FIG. 5, as described above, the entirety of the first signal line 731 overlaps the second signal line 732 in the connecting portion 722 when viewed from the second direction Ax2. However, the present invention is not limited to this example, and a portion of the first signal line 731 may overlap the second signal line 732. That is, as seen from the second direction Ax2, at least a portion of the first signal line 731 in the connecting portion 722 may overlap the second signal line 732. In this way, the minimum width Wmc of the connecting portion 722 in the third direction Ax3 can be made smaller.

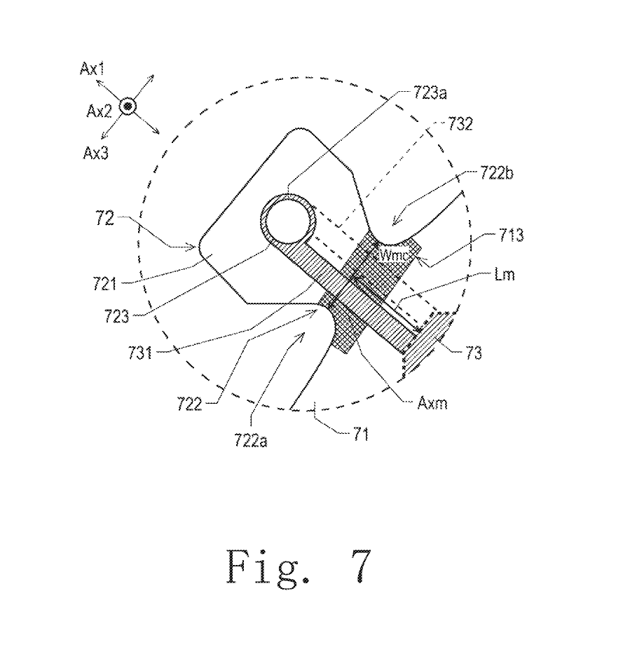

Alternatively, unlike the example illustrated in FIG. 5, the first signal line 731 does not need to overlap the second signal line 732 in the connecting portion 722 when viewed from the second direction Ax2. FIG. 7 is a top view illustrating another wiring example of the first signal line 731 and the second signal line 732. Further, note that FIG. 7 corresponds to the portion surrounded by the circular broken line in FIG. 3.

For example, as seen from the second direction Ax2, in the connecting portion 722, as illustrated in FIG. 7, the first signal line 731 may be located on one side or the other side of the second signal line 732 in the third direction Ax3. The ductility of the first signal line 731 and the second signal line 732 is higher than that of the board 71 and the protruding portion 72. In the configuration of FIG. 7, the first signal line 731 and the second signal line 732 do not overlap at the connecting portion 722 of the circuit board 7. In the configuration of FIG. 5, the first signal line 731 and the second signal line 732 overlap. Therefore, in the configuration of FIG. 7, in comparison with the configuration of FIG. 5, because the first signal line 731 and the second signal line 732 become more separated from each other after the first signal line 731 and the second signal line 732 have been cut it is difficult to maintain electrical connection at the cut surface. Therefore, the electrical connection between the first signal line 731 and the second signal line 732 in the protruding portion 72 can be more easily cut.

According to the embodiment described above, the circuit board 7 to be mounted on the motor 110 includes the board 71, which is plate-like, the wiring portions 73, the protruding portion 72, the upper surface 70a, and the lower surface 70b. The wiring portions 73 are provided on the board 71. The protruding portion 72 protrudes from an end portion of the board 71 in the first direction Ax1 perpendicular or substantially perpendicular to the thickness direction of the board 71. The upper surface 70a is the first surface on one side in the second direction Ax2 parallel or substantially parallel to the thickness direction of the board 71. The lower surface 70b is the second surface on the other side in the second direction Ax2. The wiring portions 73 include the first signal line 731 and the second signal line 732. The first signal line 731 is provided on the upper surface 70a of both the board 71 and the protruding portion 72. The second signal line 732 is provided on the lower surface 70b of both the board 71 and the protruding portion 72, and is electrically connected to the first signal line 731 at the protruding portion 72.

The embodiments of the present invention have been described above. Further, the scope of the present invention is not limited to the above-described embodiment. The present invention can be implemented with various modifications without departing from the gist of the invention. In addition, the above-described embodiments can be arbitrarily combined as appropriate.

For example, in the above embodiment, the case where the fan motor 100 using the motor 110 including the circuit board 7 is mounted on a dryer is exemplified, but the present invention is not limited to this example and the present invention may be applied to a fan motor to be mounted on an apparatus other than a dryer.

The present invention can be applied to other blowing devices such as a fan, a ventilator, and the like in addition to a dryer and furthermore can be applied to a small suction device such as a handy cleaner and also to electrical appliances with other uses such as hair curlers.

What is claimed is:

1. A circuit board to be mounted on a motor, the circuit board comprising:
a board that is plate-shaped;
a protruding portion protruding from an end portion of the board in a first direction perpendicular or substantially perpendicular to a thickness direction of the board;
wiring portions provided on the board;
a first surface on one side in a second direction parallel or substantially parallel to the thickness direction of the board; and
a second surface on another side in the second direction; wherein
the wiring portions include:
a first signal line provided on the first surface of both the board and the protruding portion; and
a second signal line provided on the second surface of both the board and the protruding portion and electrically connected to the first signal line at the protruding portion.

2. The circuit board according to claim 1, wherein the protruding portion includes:
a connecting portion extending from the end portion of the board in the first direction; and
a tip portion provided at a tip of the connecting portion; wherein
a minimum width direction is a direction intersecting the first direction and perpendicular or substantially perpendicular to the second direction and is a direction in which a width of the connecting portion is minimum;
a minimum width of the connecting portion in the minimum width direction is smaller than a width of the tip portion in a third direction perpendicular or substantially perpendicular to the first direction and the second direction.

3. The circuit board according to claim 2, wherein the protruding portion further includes:
a first recessed portion that is recessed toward another side in the third direction on one side of the protruding portion in the third direction; and
a second recessed portion that is recessed toward the one side in the third direction on the other side of the protruding portion in the third direction.

4. The circuit board according to claim 2, wherein at least one of a length of the tip portion in the first direction and the width of the tip portion in the third direction is larger than a thickness of the connecting portion in the second direction.

5. The circuit board according to claim 2, wherein at least one portion of the first signal line overlaps with the second signal line in the connecting portion when viewed from the second direction.

6. The circuit board according to claim 2, wherein, when viewed from the second direction, in the connecting portion, the first signal line is located on the one side or the other side of the second signal line in the minimum width direction.

7. The circuit board according to claim 2, wherein a direction in which the first signal line and the second signal line extend is perpendicular or substantially perpendicular to the minimum width direction.

8. The circuit board according to claim 2, wherein in the second direction, a thickness of the first signal line and a thickness of the second signal line are each smaller than the thickness of the connecting portion.

9. The circuit board according to claim 2, wherein the wiring portions other than the first signal line and the second signal line are disposed apart from a position where the width of the connecting portion is minimum in the minimum width direction by a distance larger than a thickness of the board.

10. The circuit board according to claim 2, wherein, in the connecting portion, a mark portion is provided on at least one of the first surface and the second surface.

11. The circuit board according to claim 10, wherein the mark portion is further provided on the connecting portion or across the connecting portion and the board on at least one of the first surface and the second surface of the board.

12. The circuit board according to claim 2, wherein the board includes a piece facing the protruding portion on at least one side in the third direction.

13. The circuit board according to claim 1, wherein
the board includes a composite resin material containing fibers;
the first direction in which the protruding portion protrudes diagonally intersects a longitudinal direction of the fibers.

14. A motor comprising:
a rotor that is rotatable about a central axis;
a stator that drives the rotor; and
the circuit board according to claim 1, which is electrically connected to a drive control unit that drives the rotor in a plurality of drive modes; wherein
when electrical connection between the first signal line and the second signal line is established, the rotor is drivable in a first drive mode; and
when electrical connection between the first signal line and the second signal line is cut, the rotor is drivable in a second drive mode.

15. The motor according to claim 14, wherein an end portion on one side of the first signal line in the first direction and an end portion on the one side of the second signal line in the first direction when viewed from an axial direction are located on a radial-direction outer side of the stator.

16. The motor according to claim 14, wherein in the first direction, a portion of the protruding portion that has a smallest width in a direction intersecting the first direction and perpendicular or substantially perpendicular to the second direction is located on the radial-direction outer side of the stator.

17. A fan motor comprising:
an impeller including a plurality of blades rotatable about the central axis; and
the motor according to claim 14, which drives the impeller.
